(19) United States
(12) Patent Application Publication
(10) Pub. No.: US 2014/0357063 A1
(43) Pub. Date: Dec. 4, 2014

(54) MANUFACTURING METHODS OF SEMICONDUCTOR SUBSTRATES

(71) Applicants: GREENCORE TECHNOLOGY CO. LTD., Guishan Township (TW); NANOCRYSTAL (ASIA) INC., Taipei (TW)

(72) Inventors: Chong-Ming LEE, Taipei (TW); Chung-Hua LEE, Guishan Township (TW)

(21) Appl. No.: 13/943,178

(22) Filed: Jul. 16, 2013

(30) Foreign Application Priority Data
May 28, 2013 (TW) 102118842

(51) Int. Cl. H01L 21/02

(52) U.S. Cl. CPC H01L 21/02647; H01L 21/02381; H01L 21/02378; H01L 21/0242
USPC 438/481; 438/478

(57) ABSTRACT

The present invention discloses manufacturing methods of semiconductor substrates. The method includes following steps: providing a semiconductor substrate with a nucleation layer, forming a microparticle etching mask on the nucleation layer, etching the nucleation layer, filling sol-gel into etched notches of the semiconductor substrate, removing the microparticle etching mask, performing growth of epitaxy rods and performing lateral connection of the top of the epitaxy rods to form a defect-free semiconductor substrate. The production methods of the present invention can confine the defects from the nucleation layer or the epitaxy rods to the epitaxy rods so as to generate a defect-free semiconductor substrate, that is, a semiconductor substrate with a defect-free growth film, after the lateral connection of the top of the epitaxy rods.

### BACKGROUND OF THE INVENTION

1. Technical Field

The present invention relates to methods of manufacturing semiconductor substrates, and more particularly, to a method of manufacturing semiconductor substrates with a defect-free flat connection film.

2. Description of Related Art

According to related prior art, in the presence of additives of different concentrations, epitaxy rods undergo epitaxy lateral overgrowth in order to manufacture a film on a semiconductor substrate. The additives cause each of the epitaxy rods to widen independently, vertically, upward, and gradually. Considering that additives of a specific concentration cause the epitaxy rods to widen laterally only to a certain limit, the ultimate width of the epitaxy rods can be controlled by different concentration gradients of the additives. After undergoing multiple instances of additive concentration adjustments, adjacent epitaxy rods begin to connect to each other and thereby form a film at the tops of the epitaxy rods.

As regards the growth of the film on a conventional semiconductor substrate, the vertical growth of the epitaxy rods is sensitive to additive concentration. However, additive concentration-based control of epitaxy rod width is predisposed to discrepancy in epitaxy rod height; as a result, bump defects are formed on the surface of the film on the epitaxy rods. The bump defects are 2.5 μm to 4.5 μm high and occupy a large area, i.e., 5 μm×12 μm.

The combination of uneven film surface and semiconductor lattice dislocation renders the film structurally weak and brittle. The phenomenon reduces quantum efficiency and electron-hole recombination rate of the overall epitaxial structure of a light-emitting diode (LED), when it comes to LED manufacturing, and thus reduces the light output efficiency of the LED.

Accordingly, manufacturing semiconductor substrates with a defect-free flat connection film is one of the important topics on semiconductor and LED industry, R&D, and manufacturing nowadays.

### SUMMARY OF THE INVENTION

The present invention provides a method of manufacturing semiconductor substrates. The method comprises the steps of: providing a semiconductor substrate with a nucleation layer, forming a microparticle etching mask on the nucleation layer, etching the nucleation layer, filling sol-gel into etched notches, removing the microparticle etching mask, growing epitaxy rods, and performing collateral connection of the top of the epitaxy rods to form a defect-free semiconductor substrate. With the method of the present invention, defects arising from the nucleation layer or growth of the epitaxy rods are confined to the epitaxy rods, and the tops of the epitaxy rods are collaterally connected to finalize the formation of a semiconductor substrate with a defect-free flat connection film.

The present invention further provides a method of manufacturing semiconductor substrates. The method comprises the steps of: providing a semiconductor substrate with a nucleation layer, wherein the nucleation layer grows on an upper surface of the semiconductor substrate; forming a microparticle etching mask on the nucleation layer by covering the nucleation layer with a plurality of microparticles and condensing the microparticles to form a plurality of gaps between the microparticles; etching the nucleation layer by etching the nucleation layer through the microparticle etching mask and forming a plurality of etched notches on the nucleation layer not covered with the microparticle etching mask; filling sol-gel into the etched notches; removing the microparticle etching mask to expose the nucleation layer below, such that the exposed nucleation layer provides a plurality of epitaxial growth surfaces; growing a plurality of epitaxy rods by performing vertical and lateral epitaxial growth on the epitaxial growth surfaces; and performing collateral connection of tops of the epitaxy rods to form a defect-free semiconductor substrate by continuing the vertical and lateral epitaxial growth until the tops of the epitaxy rods are collaterally connected to form the defect-free semiconductor substrate with a flat connection film.

The present invention further provides a method of manufacturing semiconductor substrates. The method comprises the steps of: providing a semiconductor substrate with a nucleation layer, wherein the nucleation layer grows on an upper surface of the semiconductor substrate; forming a photoresist etching mask on the nucleation layer by applying a photoresist to the nucleation layer and then performing impression, exposure and development on the photoresist to form the photoresist etching mask, wherein the photoresist etching mask has a plurality of openings whereby a portion of the nucleation layer is exposed; etching the nucleation layer through the openings and forming a plurality of etched notches on the nucleation layer in a manner that the etched notches correspond in position to the openings, respectively; removing the photoresist etching mask by a polishing process or a chemical etching process to expose the nucleation layer below, such that the exposed nucleation layer provides a plurality of epitaxial growth surfaces; filling sol-gel into the etched notches in a manner that the sol-gel does not cover the epitaxial growth surfaces; growing a plurality of epitaxy rods by performing vertical and lateral epitaxial growth on the epitaxial growth surfaces; and performing collateral connection of tops of the epitaxy rods to form a defect-free semiconductor substrate by continuing the vertical and lateral epitaxial growth until the tops of the epitaxy rods are collaterally connected to form the defect-free semiconductor substrate with a flat connection film.

Implementation of the present invention at least involves the following inventive steps:

1. the defect-free semiconductor substrate thus manufactured enhances the quantum efficiency of epitaxial structure of LED subsequently formed thereon and increases the light output efficiency of the LED; and

2. the gaps between adjacent epitaxy rods not only reduce greatly the total internal reflection of light rays which fall on the epitaxy rods, but also increase the scattering angle of the incident light rays, so as to enhance the overall light output efficiency of light-emitting elements.

The features and advantages of the present invention are detailed hereinafter with reference to the preferred embodiments. The detailed description is intended to enable a person skilled in the art to gain insight into the technical contents disclosed herein and implement the present invention accordingly. In particular, a person skilled in the art can easily understand the objects and advantages of the present invention by referring to the disclosure of the specification, the claims, and the accompanying drawings.

### BRIEF DESCRIPTION OF THE SEVERAL VIEWS OF THE DRAWINGS

The invention as well as a preferred mode of use, further objectives and advantages thereof will be best understood by reference to the following detailed description of illustrative embodiments when read in conjunction with the accompanying drawings, wherein:

FIG. 1 is a flow chart of a method of manufacturing semiconductor substrates according to the embodiment of the present invention;

FIG. 2 is a cross-sectional view of a nucleation layer covered with microparticles according to the embodiment of the present invention;

FIG. 3 is a cross-sectional view of the microparticles condensed to form gaps therebetween according to the embodiment of the present invention;

FIG. 4A is a cross-sectional view of the nucleation layer etched to form etched notches according to the embodiment of the present invention;

FIG. 4B is a cross-sectional view of the etched notches filled with sol-gel according to the embodiment of the present invention;

FIG. 5 is a cross-sectional view of exposed epitaxial growth surfaces according to the embodiment of the present invention;

FIG. 6 is a cross-sectional view of upward vertical growth of epitaxy rods according to the embodiment of the present invention;

FIG. 7 is a cross-sectional view of lateral growth of epitaxy rods according to the embodiment of the present invention;

FIG. 8 is a cross-sectional view of the epitaxy rods grown laterally and then grown upward according to the embodiment of the present invention;

FIG. 9 is a cross-sectional view of the epitaxy rods with their tops collaterally connected according to the embodiment of the present invention;

FIG. 10 is a flow chart of another method of manufacturing semiconductor substrates according to the embodiment of the present invention;

FIG. 11 is a cross-sectional view of a photoresist etching mask according to the embodiment of the present invention;

FIG. 12 is a cross-sectional view of etched notches according to the embodiment of the present invention; and

FIG. 13 is a cross-sectional view of the etched notches filled with sol-gel according to the embodiment of the present invention.

### DETAILED DESCRIPTION OF THE EMBODIMENT OF THE INVENTION

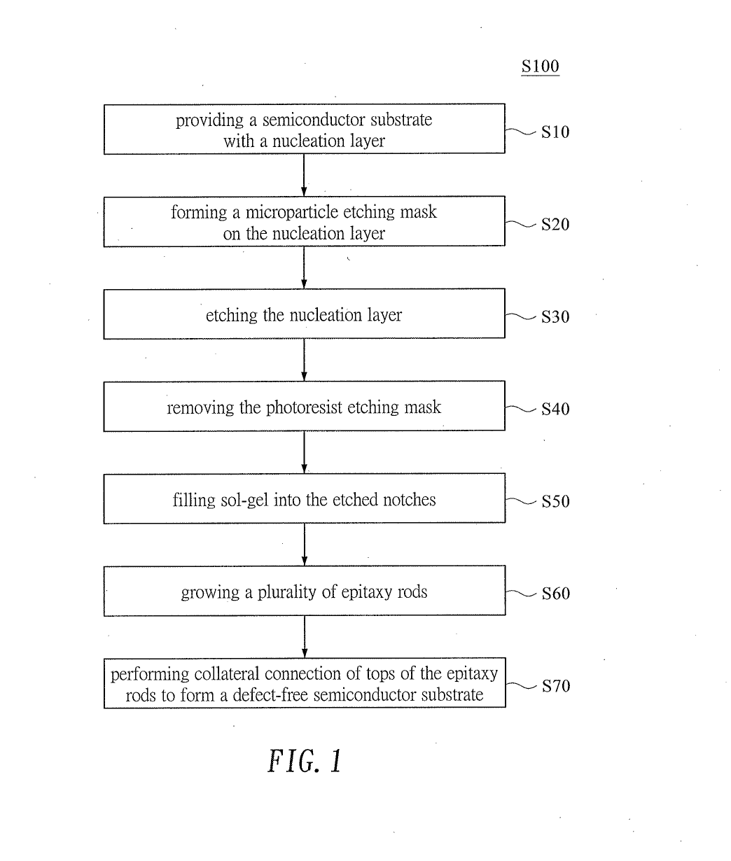

Referring to FIG. 1, in this embodiment, a method S100 of manufacturing semiconductor substrates comprises the steps of: providing a semiconductor substrate with a nucleation layer (step S10); forming a microparticle etching mask on the nucleation layer (step S20); etching the nucleation layer (step S30); filling sol-gel into the etched notches (step S40); removing the microparticle etching mask (step S50); growing a plurality of epitaxy rods (step S60); and performing collateral connection of tops of the epitaxy rods to form a defect-free semiconductor substrate (step S70).

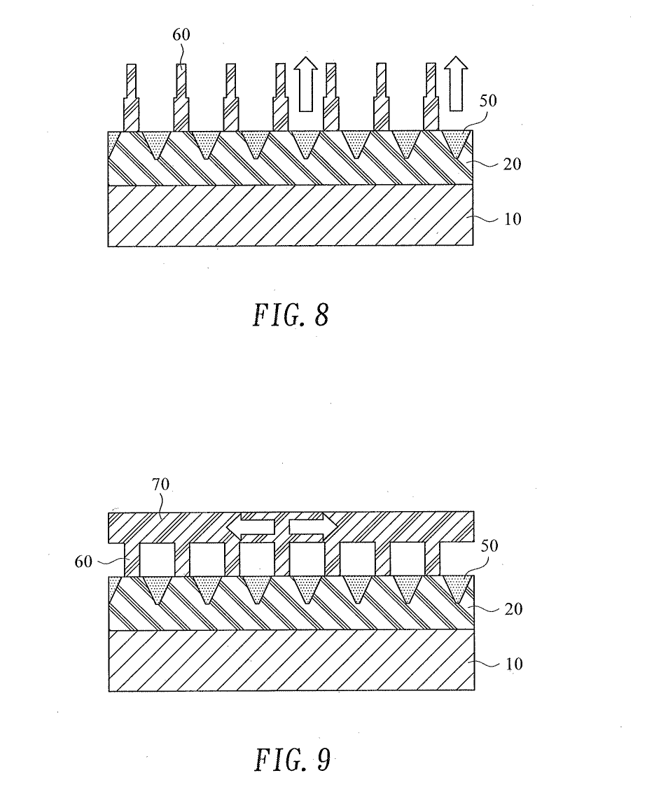

Referring to FIG. 1 through FIG. 13, in the step of providing a semiconductor substrate with a nucleation layer (step S10), a nucleation layer 20 grows on an upper surface of a semiconductor substrate 10. The semiconductor substrate 10 is a sapphire substrate, a silicon (Si) substrate, or a silicon carbide (SiC) substrate. The nucleation layer 20 is made of gallium nitride (GaN), aluminum nitride (AlN), indium nitride (InN), indium gallium nitride (InGaN), aluminum gallium nitride (AlGaN), or aluminum indium gallium nitride (AlInGaN).

Referring to FIG. 1 through FIG. 3, the step of forming a microparticle etching mask 31 on the nucleation layer 20 (step S20) entails covering the nucleation layer 20 with a plurality of microparticles 30 and condensing the microparticles 30 to form a plurality of gaps 32 between the microparticles 30.

The microparticles 30 are organic microparticles or inorganic microparticles, or consist of a mixture of organic microparticles and inorganic microparticles. The organic microparticles are made of an organic material, such as polystyrene, poly(methyl methacrylate) (PMMA), melamine, or polycarbonate (PC). The inorganic microparticles are made of an inorganic material, such as silicon oxide, titanium oxide, zirconium oxide, zinc oxide, tin oxide, or aluminum oxide.

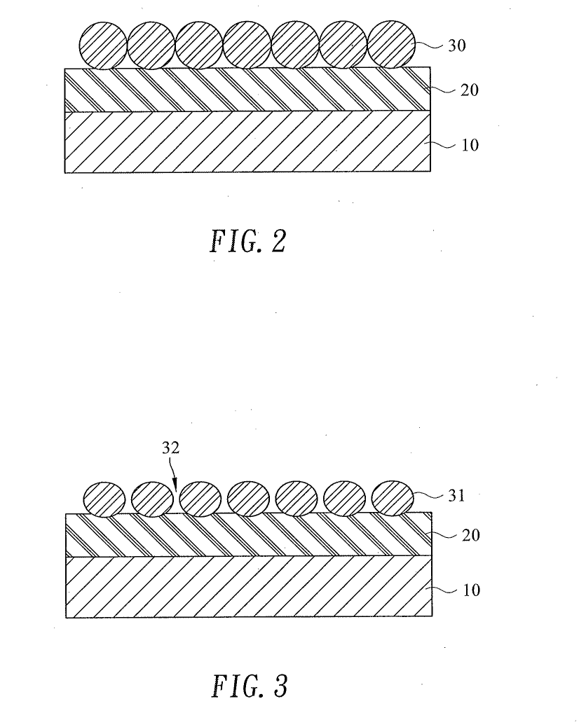

Referring to FIG. 2 and FIG. 3, after the nucleation layer 20 has been covered with the microparticles 30, it is necessary to condense the microparticles 30. If the microparticles 30 are organic microparticles, the organic microparticles can be condensed by means of oxygen plasma. If the microparticles 30 are inorganic microparticles, the inorganic microparticles can be condensed by means of dilute hydrofluoric acid or weak alkali micro-etching. Referring to FIG. 3, the microparticle etching mask 31 is formed as a result of condensing the microparticles 30 to form the gaps 32 between the microparticles 30.

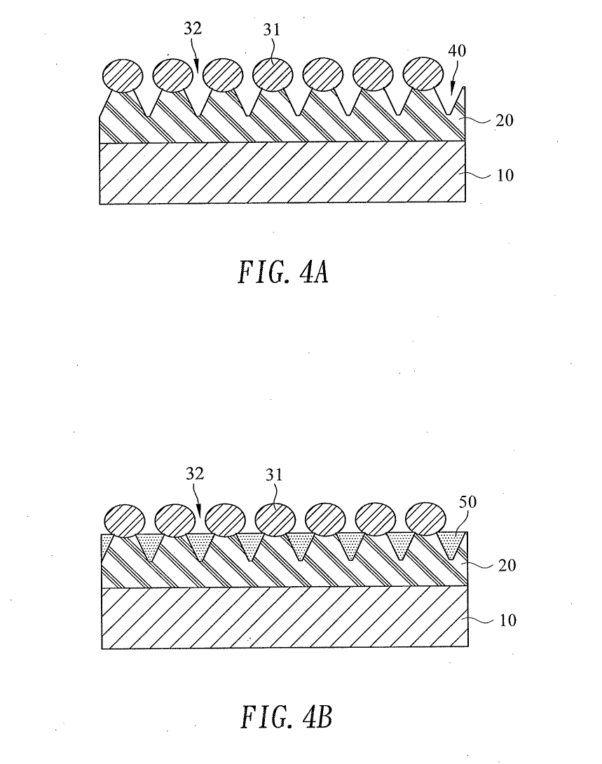

Referring to FIG. 1, FIG. 3 and FIG. 4A, in the step of etching the nucleation layer 20 (step S30), the nucleation layer 20 is etched through the microparticle etching mask 31, and a plurality of etched notches 40 is formed at the nucleation layer 20 not covered with the microparticle etching mask 31, that is, at the nucleation layer 20 beneath the gaps 32.

Referring to FIG. 1 and FIG. 4B, in the step of filling sol-gel into the etched notches (step S40), the etched notches 40 are filled with sol-gel 50, for example, the etched notches 40 are each filled with the sol-gel 50 in a manner that an upper surface of the sol-gel 50 and an upper surface of the nucleation layer 20 are coplanar, wherein the sol-gel 50 is formed from silicon oxide, titanium oxide, zirconium oxide, zinc oxide, tin oxide, aluminum oxide, or a combination thereof mixed in any proportion.

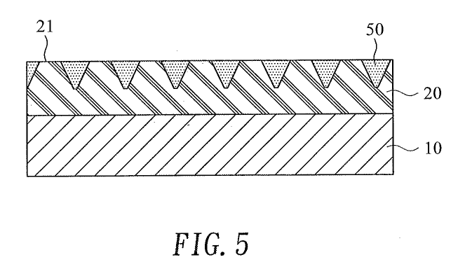

Referring to FIG. 1 and FIG. 5, in the step of removing the microparticle etching mask (step S50), the microparticle etching mask 31 is removed with oxygen plasma, hydrofluoric acid or strong alkali to expose the nucleation layer 20 below, such that the surface of the nucleation layer 20 thus exposed functions as a plurality of epitaxial growth surfaces 21. If the microparticle etching mask 31 comprises organic microparticles, the microparticle etching mask 31 can be removed with oxygen plasma. If the microparticle etching mask 31 comprises inorganic microparticles, the microparticle etching mask 31 can be removed with hydrofluoric acid or strong alkali.

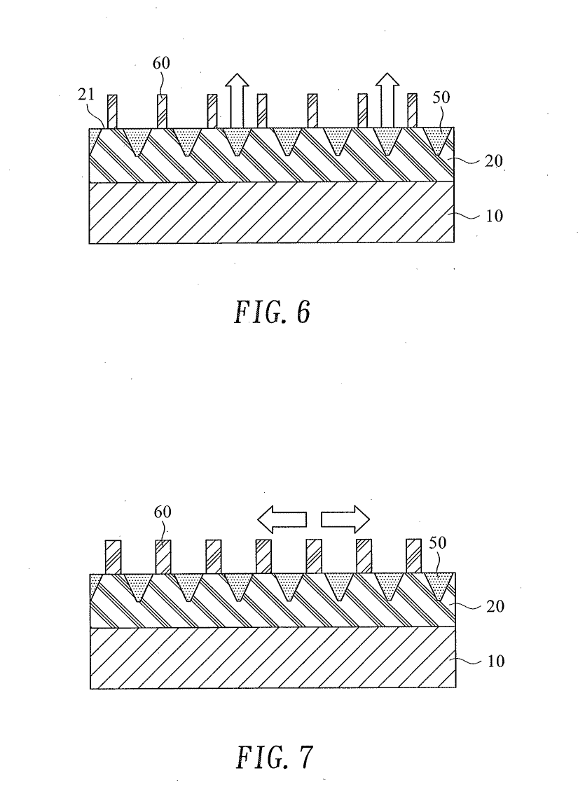

Referring to FIG. 1, and FIG. 6 through FIG. 8, the step of growing epitaxy rods (step S60) entails performing vertical and lateral epitaxial growth on the epitaxial growth surfaces 21 to form a plurality of epitaxy rods 60. The epitaxy rods 60 undergo vertical and lateral epitaxial growth on the epitaxial growth surfaces 21 simultaneously. Since the etched notches 40 have been filled with the sol-gel 50, the epitaxy rods 60 do not grow inside the etched notches 40.

Referring to FIG. 1 and FIG. 9, the step of performing collateral connection of the tops of the epitaxy rods to form a defect-free semiconductor substrate (step S70) entails continuing the vertical and lateral epitaxial growth until the tops of the epitaxy rods 60 are collaterally connected to form the defect-free semiconductor substrate 10 with a flat connection film 70, that is, a defect-free semiconductor substrate 100.

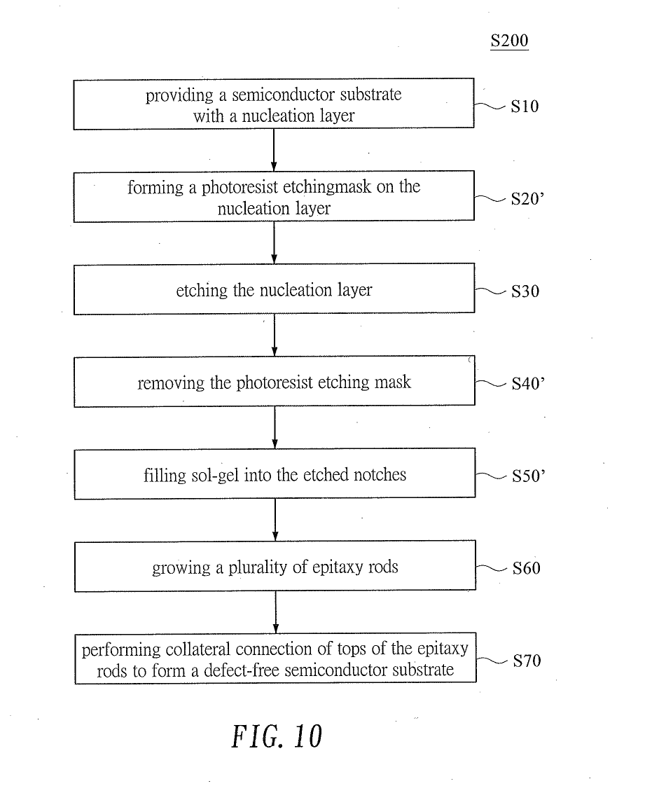

Referring to FIG. 10, in this embodiment, another method S200 of manufacturing semiconductor substrates comprises the steps of: providing a semiconductor substrate with a nucleation layer (step S10); forming a photoresist etching mask on the nucleation layer (step S20′); etching the nucleation layer (step S30); removing the photoresist etching mask (step S40′); filling sol-gel into the etched notches (step S50′); growing epitaxy rods (step S60); and performing collateral connection of the tops of the epitaxy rods to form a defect-free semiconductor substrate (step S70).

Referring to FIG. 10, the step of providing a semiconductor substrate with a nucleation layer (step S10) is described above and thus is not described in detail herein for the sake of brevity.

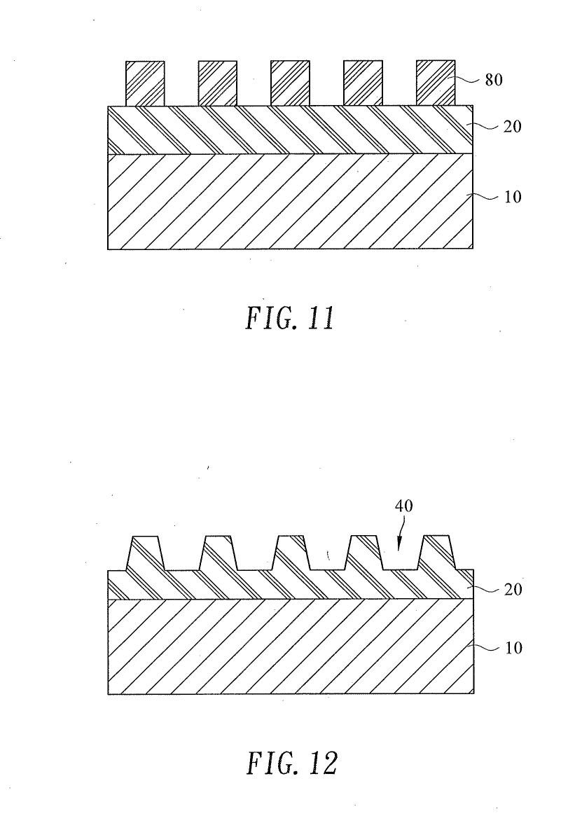

Referring to FIG. 10 and FIG. 11, in the step of forming a photoresist etching mask on the nucleation layer (step S20′), a photoresist is applied to the nucleation layer 20, and then the photoresist undergoes impression, exposure and development to form a photoresist etching mask 80, wherein the photoresist etching mask 80 has a plurality of openings 81 whereby a portion of the nucleation layer 20 is exposed.

Referring to FIG. 10 through FIG. 12, the step of etching the nucleation layer (step S30) entails etching the nucleation layer 20 through the openings 81 of the photoresist etching mask 80 and forming the plurality of etched notches 40 on the nucleation layer 20 in a manner that the etched notches 40 correspond in position to the openings 81, respectively.

Referring to FIG. 10 through FIG. 12, the step of removing the photoresist etching mask (step S40′) entails removing the photoresist etching mask 80 by a polishing process or a chemical etching process to expose the nucleation layer 20 below, such that the surface of the nucleation layer 20 thus exposed functions as the plurality of epitaxial growth surfaces 21.

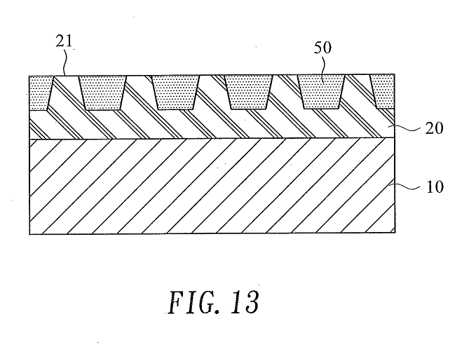

Referring to FIG. 10 and FIG. 13, in the step of filling sol-gel into the etched notches (step S50′), the sol-gel 50 fills the etched notches 40 without covering the epitaxial growth surfaces 21, wherein the sol-gel 50 is made of a material described above.

Referring to FIG. 10, the step of growing epitaxy rods (step S60) and the step of performing collateral connection of the tops of the epitaxy rods to form a defect-free semiconductor substrate (step S70) are identical to that illustrated with FIG. 6 through FIG. 9.

In conclusion, in this embodiment, with the methods S100, S200 of manufacturing semiconductor substrates, the gaps between adjacent epitaxy rods 60 of the defect-free semiconductor substrate 100 thus manufactured not only reduce greatly the total internal reflection of light rays which fall on the epitaxy rods 60, but also increase the scattering angle of the incident light rays, so as to enhance the overall light output efficiency of light-emitting elements to thereby be applicable to substrates for use with light-emitting diodes, and enhance the quantum efficiency of the epitaxial structure of the light-emitting diodes to thereby enhance the overall light output efficiency of the light-emitting diodes.

The embodiments described above are intended only to demonstrate the technical concept and features of the present invention so as to enable a person skilled in the art to understand and implement the contents disclosed herein. It is understood that the disclosed embodiments are not to limit the scope of the present invention. Therefore, all equivalent changes or modifications based on the concept of the present invention should be encompassed by the appended claims.

What is claimed is:

1. A method of manufacturing semiconductor substrates, the method comprising the steps of:
providing a semiconductor substrate with a nucleation layer, wherein the nucleation layer grows on an upper surface of the semiconductor substrate;
forming a microparticle etching mask on the nucleation layer by covering the nucleation layer with a plurality of microparticles and condensing the microparticles to form a plurality of gaps between the microparticles;
etching the nucleation layer by etching the nucleation layer through the microparticle etching mask and forming a plurality of etched notches at the nucleation layer not covered with the microparticle etching mask;
filling sol-gel into the etched notches;
removing the microparticle etching mask to expose the nucleation layer below, wherein the exposed nucleation layer provides a plurality of epitaxial growth surfaces;
growing a plurality of epitaxy rods by performing vertical and lateral epitaxial growth on the epitaxial growth surfaces; and
performing collateral connection of tops of the epitaxy rods to form a defect-free semiconductor substrate by continuing the vertical and lateral epitaxial growth until the tops of the epitaxy rods are collaterally connected to form the defect-free semiconductor substrate with a flat connection film.

2. The method of claim 1, wherein the step of removing the microparticle etching mask is performed by one of oxygen plasma, hydrofluoric acid, and strong alkali.

3. The method of claim 1, wherein the microparticles are organic microparticles or inorganic microparticles, or consist of a mixture of organic microparticles and inorganic microparticles, wherein the organic microparticles are made of one of polystyrene, poly(methyl methacrylate), melamine, and polycarbonate, wherein the inorganic microparticles are made of one of silicon oxide, titanium oxide, zirconium oxide, zinc oxide, tin oxide, and aluminum oxide.

4. The method of claim 3, wherein the step of condensing the microparticles is performed by condensing the organic microparticles with oxygen plasma or condensing the inorganic microparticles with dilute hydrofluoric acid or weak alkali micro-etching.

5. A method of manufacturing semiconductor substrates, the method comprising the steps of:
providing a semiconductor substrate with a nucleation layer, wherein the nucleation layer grows on an upper surface of the semiconductor substrate;
forming a photoresist etching mask on the nucleation layer by applying a photoresist to the nucleation layer and then performing impression, exposure and development on the photoresist to form the photoresist etching mask, wherein the photoresist etching mask has a plurality of openings whereby a portion of the nucleation layer is exposed;
etching the nucleation layer through the openings and forming a plurality of etched notches on the nucleation layer in a manner that the etched notches correspond in position to the openings, respectively;
removing the photoresist etching mask by a polishing process or a chemical etching process to expose the nucleation layer below, such that the exposed nucleation layer provides a plurality of epitaxial growth surfaces;
filling sol-gel into the etched notches in a manner that the sol-gel does not cover the epitaxial growth surfaces;
growing a plurality of epitaxy rods by performing vertical and lateral epitaxial growth on the epitaxial growth surfaces; and
performing collateral connection of tops of the epitaxy rods to form a defect-free semiconductor substrate by continuing the vertical and lateral epitaxial growth until the tops of the epitaxy rods are collaterally connected to form the defect-free semiconductor substrate with a flat connection film.

6. The method of claim 5, wherein the step of removing the photoresist etching mask is performed by one of polishing and chemical etching.

7. The method of claim 1, wherein the semiconductor substrate is one of a sapphire substrate, a silicon substrate, and a silicon carbide substrate.

8. The method of claim 1, wherein the nucleation layer is made of one of gallium nitride, aluminum nitride, indium nitride, indium gallium nitride, aluminum gallium nitride, and aluminum indium gallium nitride.

9. The method of claim 1, wherein the sol-gel is made of one of silicon oxide, titanium oxide, zirconium oxide, zinc oxide, tin oxide, aluminum oxide, and a mixture thereof.

10. The method of claim 5, wherein the semiconductor substrate is one of a sapphire substrate, a silicon substrate, and a silicon carbide substrate.

11. The method of claim 5, wherein the nucleation layer is made of one of gallium nitride, aluminum nitride, indium nitride, indium gallium nitride, aluminum gallium nitride, and aluminum indium gallium nitride.

12. The method of claim 5, wherein the sol-gel is made of one of silicon oxide, titanium oxide, zirconium oxide, zinc oxide, tin oxide, aluminum oxide, and a mixture thereof.
